(19) United States
(12) Patent Application Publication
(10) Pub. No.: US 2026/0110764 A1
(43) Pub. Date: Apr. 23, 2026

(54) MAGNETIC RESONANCE IMAGING APPARATUS AND METHOD

(71) Applicant: Canon Medical Systems Corporation, Otawara-shi (JP)

(72) Inventor: Hidenori TAKESHIMA, Tokyo (JP)

(73) Assignee: Canon Medical Systems Corporation, Otawara-shi (JP)

(21) Appl. No.: 19/348,851

(22) Filed: Oct. 3, 2025

(30) Foreign Application Priority Data
Oct. 17, 2024 (JP) 2024-181915

(51) Int. Cl. G01R 33/44; G01R 33/54; G01R 33/56

(52) U.S. Cl. CPC G01R 33/443; G01R 33/543; G01R 33/5608

(57) ABSTRACT

A magnetic resonance imaging apparatus according to embodiments includes an imaging mechanism configured to perform MR imaging, and processing circuitry configured to control the imaging mechanism to perform shimming imaging to acquire a first magnetic field distribution map having a first spatial resolution, control the imaging mechanism to perform first MR imaging to acquire a first anatomical image having a second spatial resolution higher than the first spatial resolution, and generate a second magnetic field distribution map having a third spatial resolution higher than the first spatial resolution by using the first magnetic field distribution map, the first anatomical image, and/or a processed image having enhanced boundaries of anatomical regions included in the first anatomical image.

### CROSS-REFERENCE TO RELATED APPLICATIONS

This application is based upon and claims the benefit of priority from Japanese Patent Application No. 2024-181915, filed Oct. 17, 2024, the entire contents of which are incorporated herein by reference.

### FIELD

Embodiments disclosed in the present specification and drawings relate to a magnetic resonance imaging apparatus and a method.

### BACKGROUND

In magnetic resonance imaging, shimming is performed to ensure uniformity of a magnetic field. The following processing is performed in shimming:
(1) performing shimming imaging to generate a magnetic field distribution map representing a degree of spatial disorder of a static magnetic field with respect to a position,
(2) calculating a correction magnetic field coefficient for spatially uniformizing the static magnetic field, and
(3) applying a correction magnetic field according to a correction magnetic field coefficient.

To ensure the quality of shimming, accuracy of the magnetic field distribution map generated in the processing (1) is important. Even though performing shimming imaging with a high spatial resolution improves accuracy of the correction magnetic field coefficient, the imaging time of the shimming imaging increases when the spatial resolution is increased. Since the shimming imaging is not performed for acquisition of diagnostic images, shorter imaging time is desirable.

### BRIEF DESCRIPTION OF THE DRAWINGS

FIG. 1 is a diagram illustrating an example of a configuration of a magnetic resonance imaging apparatus according to a first embodiment.

FIG. 2 is a diagram illustrating an example of processing for generating a trained model according to the present embodiment.

FIG. 3 is a flowchart illustrating typical magnetic resonance (MR) inspection by the magnetic resonance imaging apparatus according to the present embodiment.

FIG. 4 is a diagram illustrating an example of a screen displaying graphical user interface (GUI) buttons for issuance of an instruction to update a shimming map.

FIG. 5 is a diagram illustrating an example of an initial editing screen of an imaging protocol.

FIG. 6 is a diagram illustrating an example of an edited editing screen of the imaging protocol.

FIG. 7 is a diagram illustrating an example of inputs and an output of a trained model according to a second modification.

FIG. 8 is a diagram illustrating an example of a network configuration of a trained model according to a third modification.

FIG. 9 is a diagram illustrating an example of a network configuration of a trained model according to a fourth modification.

### DETAILED DESCRIPTION

A magnetic resonance imaging apparatus according to embodiments includes an imaging mechanism configured to perform MR imaging, and processing circuitry configured to control the imaging mechanism to perform shimming imaging to acquire a first magnetic field distribution map having a first spatial resolution, control the imaging mechanism to perform first MR imaging to acquire a first anatomical image having a second spatial resolution higher than the first spatial resolution, and generate a second magnetic field distribution map having a third spatial resolution higher than the first spatial resolution by using the first magnetic field distribution map, the first anatomical image, and/or a processed image having enhanced boundaries of anatomical regions included in the first anatomical image.

Various embodiments will be described hereinafter with reference to the accompanying drawings.

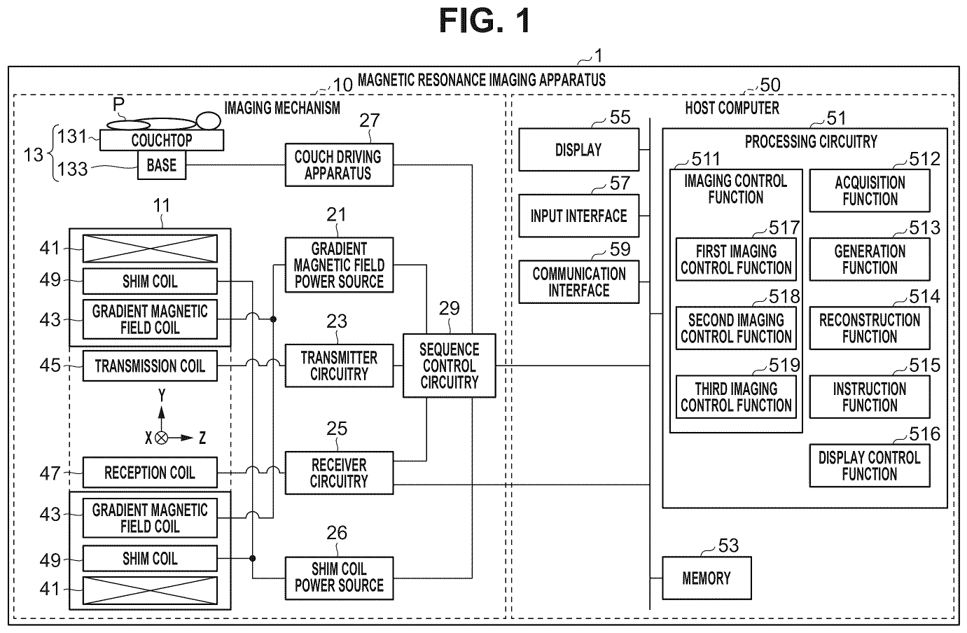

FIG. 1 is a diagram illustrating an example of a configuration of a magnetic resonance imaging apparatus 1 according to a first embodiment. As illustrated in FIG. 1, the magnetic resonance imaging apparatus 1 includes a frame 11, a couch 13, a gradient magnetic field power source 21, transmitter circuitry 23, receiver circuitry 25, a shim coil power source 26, a couch driving apparatus 27, sequence control circuitry 29, and a host computer 50. The frame 11, the couch 13, the gradient magnetic field power source 21, the transmitter circuitry 23, the receiver circuitry 25, the shim coil power source 26, the couch driving apparatus 27, and the sequence control circuitry 29 are examples of components of an imaging mechanism 10 for performing MR imaging.

The frame 11 includes a static magnetic field magnet 41, a gradient magnetic field coil 43, and a shim coil 49. The static magnetic field magnet 41, the gradient magnetic field coil 43, and the shim coil 49 are housed in a housing of the frame 11. A bore having a hollow shape is formed in the housing of the frame 11. A transmission coil 45 and a reception coil 47 are disposed in the bore of the frame 11.

The static magnetic field magnet 41 having a hollow in an approximately cylindrical shape generates a static magnetic field in the approximately cylindrical shape. The static magnetic field magnet 41 is, for example, a permanent magnet, a superconducting magnet, a normal conduction magnet, or the like. The center axis of the static magnetic field magnet 41 is defined as a Z axis, an axis vertically perpendicularly intersecting with the Z axis is defined as a Y axis, and an axis horizontally perpendicularly intersecting with the Z axis is defined as an X axis. The X, Y, and Z axes configure an orthogonal three-dimensional coordinate system.

The gradient magnetic field coil 43 attached inside the static magnetic field magnet 41 is a coil unit formed having a hollow in an approximately cylindrical shape. The gradient magnetic field coil 43 is supplied with a current from the gradient magnetic field power source 21 to generate a gradient magnetic field. More specifically, the gradient magnetic field coil 43 includes three different coils corresponding to the X, Y, and Z axes, respectively, which perpendicularly intersect with each other. The three coils form gradient magnetic fields having magnetic field strengths varying along the X, Y, and Z axes, respectively. The gradient magnetic fields along the X, Y, and Z axes are combined to form a slice selection gradient magnetic field Gs, a phase encoding gradient magnetic field Gp, and a frequency encoding gradient magnetic field Gr perpendicularly intersecting with each other in desired directions. The slice selection gradient magnetic field Gs is used to optionally determine an imaging cross section (slice). The phase encoding gradient magnetic field Gp is used to change the phase of a magnetic resonance signal (hereinafter referred to as an MR signal) in accordance with the spatial position. The frequency encoding gradient magnetic field Gr is used to change the frequency of the MR signal corresponding to the spatial position. In the following descriptions, a gradient direction of the slice selection gradient magnetic field Gs coincides with the Z axis, a gradient direction of the phase encoding gradient magnetic field Gp coincides with the Y axis, and a gradient direction of the frequency encoding gradient magnetic field Gr coincides with the X axis.

The gradient magnetic field power source 21 supplies a current to the gradient magnetic field coil 43 according to a control signal from the sequence control circuitry 29. The gradient magnetic field power source 21 supplies a current to the gradient magnetic field coil 43, so that gradient magnetic fields along the X, Y, and Z axes are generated by the gradient magnetic field coil 43. The gradient magnetic fields are superimposed on the static magnetic field formed by the static magnetic field magnet 41, and then applied to a subject P.

The transmission coil 45 is disposed, for example, inside the gradient magnetic field coil 43 and supplied with a current from the transmitter circuitry 23 to generate a high-frequency pulse (hereinafter referred to as a radio frequency (RF) pulse).

The transmitter circuitry 23 supplies a current to the transmission coil 45 to apply an RF pulse, which excites target protons, such as hydrogen nuclei, existing in the subject P, to the subject P via the transmission coil 45. The RF pulse vibrates at a resonance frequency specific to the target protons to excite the target protons. An MR signal is generated by the excited target protons and detected by the reception coil 47. The transmission coil 45 is, for example, a whole body (WB) coil. The whole body coil may be used as a transmission and reception coil.

In response to the action of the RF pulse, the reception coil 47 receives the MR signal generated from the target protons existing in the subject P. The reception coil 47 includes a plurality of reception coil elements that can receive the MR signal. The received MR signal is supplied to the receiver circuitry 25 via a wired or wireless connection. Although not illustrate in FIG. 1, the reception coil 47 has a plurality of reception channels implemented in parallel. Each of the reception channels includes a reception coil element for receiving an MR signal, and an amplifier for amplifying the MR signal. The MR signal is output for each reception channel. The total number of reception channels may be the same as the total number of reception coil elements, or the total number of reception channels may be larger or smaller than the total number of reception coil elements.

The receiver circuitry 25 receives the MR signal generated by the excited target protons, via the reception coil 47. The receiver circuitry 25 applies signal processing to the received MR signal to generate a digital MR signal. The digital MR signal is expressed in a k-space defined by a spatial frequency. Hereinafter, the digital MR signal is referred to as k-space data. The k-space data is supplied to the host computer 50 via a wired or wireless connection.

The transmission coil 45 and the reception coil 47 are merely illustrative. A transmission and reception coil having the transmission and reception functions may be used instead of the transmission coil 45 and the reception coil 47. Alternatively, the transmission coil 45, the reception coil 47, and the transmission and reception coil may be used in combination.

The shim coil 49 is a coil unit attached inside the static magnetic field magnet 41. The shim coil 49 is supplied with a current from the shim coil power source 26 to generate a correction magnetic field for a nonuniformity correction of the static magnetic field. The nonuniformity of the static magnetic field has the zeroth-order, first-order, second-order, third-order, and higher order components. The shim coil 49 generates the correction magnetic field to correct all or some of these components.

The shim coil power source 26 supplies a current to the shim coil 49 according to a control signal from the sequence control circuitry 29. More specifically, the shim coil power source 26 receives a correction magnetic field coefficient from the sequence control circuitry 29, and supplies a current corresponding to each component of the correction magnetic field to the shim coil 49 according to the correction magnetic field coefficient. In this way, the correction magnetic field is generated from the shim coil 49. The correction magnetic field coefficient means a value of a current supplied to the shim coil 49 to uniformize the static magnetic field.

The couch 13 is installed at a position adjacent to the frame 11. The couch 13 has a couchtop 131 and a base 133. The subject P is placed on the couchtop 131. The base 133 slidably supports the couchtop 131 along the X, Y, and Z axes. The couch driving apparatus 27 is housed in the base 133. The couch driving apparatus 27 moves the couchtop 131 under control of the sequence control circuitry 29. The couch driving apparatus 27 may include, for example, any types of motors, such as a servomotor and a stepping motor.

The sequence control circuitry 29 has hardware resources including a processor, such as a Central Processing Unit (CPU) or a Micro Processing Unit (MPU) and memories, such as a Read Only Memory (ROM) and a Random Access Memory (RAM). The sequence control circuitry 29 synchronously controls the gradient magnetic field power source 21, the transmitter circuitry 23, the receiver circuitry 25, and the shim coil power source 26, based on imaging conditions set by a processing circuitry 51 to perform the MR imaging on the subject P according to the imaging conditions and acquires the k-space data related to the subject P. Examples of possible MR imaging include image capturing for anatomical image acquisition, shimming imaging for shimming, Magnetic Resonance Spectroscopy (MRS) imaging, and Chemical Exchange Saturation Transfer (CEST) imaging.

In response to the sequence control circuitry 29 performing various types of MR imaging, an MR signal is generated from the imaging region set in the subject P. The receiver circuitry 25 receives the MR signal via the reception coil 47 and applies signal processing to the received MR signal to acquire the k-space data. The acquired k-space data is digital data representing a signal strength value of the MR signal generated from the imaging region, by using a time function. The k-space data is stored in a memory 53.

As illustrated in FIG. 1, the host computer 50 includes processing circuitry 51, the memory 53, a display 55, an input interface 57, and a communication interface 59.

The processing circuitry 51 includes a processor, such as a CPU as a hardware resource. The processing circuitry 51 functions as the center of the magnetic resonance imaging apparatus 1. For example, the processing circuitry 51 executes various programs to implement an imaging control function 511, an acquisition function 512, a generation function 513, a reconstruction function 514, an instruction function 515, and a display control function 516.

The processing circuitry 51 controls the imaging mechanism 10 via the imaging control function 511 to perform various types of MR imaging on the subject P to acquire the k-space data via the receiver circuitry 25. Types of MR imaging according to the present embodiment are classified into shimming imaging, first MR imaging, second MR imaging, and the like. The shimming imaging is a type of MR imaging that is performed to acquire a first magnetic field distribution map having a first spatial resolution. The first MR imaging is a type of MR imaging that is performed to acquire a first anatomical image having a second spatial resolution higher than the first spatial resolution. The second MR imaging is a type of MR imaging that is performed to acquire a second anatomical image or an MR spectrum.

The imaging control function 511 includes a first imaging control function 517, a second imaging control function 518, and a third imaging control function 519. The processing circuitry 51 controls the imaging mechanism 10 via the first imaging control function 517 to perform shimming imaging to acquire the first magnetic field distribution map having the first spatial resolution. The first imaging control function 517 is an example of a first imaging control unit. The processing circuitry 51 controls the imaging mechanism 10 via the second imaging control function 518 to perform the first MR imaging to acquire the first anatomical image having the second spatial resolution higher than the first spatial resolution. The second imaging control function 518 is an example of a second imaging control unit. The processing circuitry 51 controls the imaging mechanism 10 via the third imaging control function 519 to perform the second MR imaging by using a second magnetic field distribution map to acquire the second anatomical image or the MR spectrum. The third imaging control function 519 is an example of the third imaging control unit.

The processing circuitry 51 acquires various types of information via the acquisition function 512. For example, the processing circuitry 51 acquires the k-space data from the receiver circuitry 25. The processing circuitry 51 can also acquire various types of information from a computer or various apparatuses connected with the magnetic resonance imaging apparatus 1 via a wired or wireless connection. The acquisition function 512 is an example of an acquisition unit.

The processing circuitry 51 generates, via the generation function 513, the second magnetic field distribution map having a third spatial resolution higher than the first spatial resolution by using the first magnetic field distribution map, the first anatomical image, and/or a processed image having enhanced boundaries of anatomical regions included in the first anatomical image.

The processing circuitry 51 reconstructs the MR image based on the k-space data via the reconstruction function 514. As an example, the processing circuitry 51 generates the first magnetic field distribution map representing the spatial distribution of a deviation of the static magnetic field, based on the k-space data acquired in the shimming imaging. The deviation of the static magnetic field can be calculated based on a phase difference divided by a time difference [rad/s]. The phase difference is a difference between two different phase images having different echo time. The phase difference is proportional to the static magnetic field intensity or the resonance frequency. The deviation of the static magnetic field may be represented by a frequency difference [Hz] by dividing the phase difference divided by the time difference by 2π. As another example, the processing circuitry 51 generates the first anatomical image representing a shape of the imaging target region in the body of the subject P, based on the k-space data acquired in the first MR imaging. As still another example, the processing circuitry 51 generates the second anatomical image or the MR spectrum based on the k-space data acquired in the second MR imaging. In a case where the second MR imaging is anatomical image capturing, the processing circuitry 51 generates the second anatomical image representing the shape of the imaging target region in the body of the subject P. In a case where the second MR imaging is MRS imaging, the processing circuitry 51 generates an MRS spectrum. In a case where the second MR imaging is CEST imaging, the processing circuitry 51 generates a Z spectrum. The reconstruction function 514 is an example of a generation unit. The MRS spectrum and the Z spectrum are examples of the MR spectrum.

After the first anatomical image has been acquired, the processing circuitry 51 issues an instruction to generate the second magnetic field distribution map, via the instruction function 515. The instruction is issued based on a user operation performed on the input interface 57. The instruction function 515 is an example of an instruction unit. In a case where an instruction to generate the second magnetic field distribution map is issued, the processing circuitry 51 generates the second magnetic field distribution map via the generation function 513.

The processing circuitry 51 displays various types of information on the display 55 via the display control function 516. As an example, the processing circuitry 51 displays a shimming map, the first anatomical image, the second anatomical image, and/or the MR spectrum. As another example, the processing circuitry 51 displays a first button indicating that the generation of the second magnetic field distribution map is required, and a second button indicating that the generation of the second magnetic field distribution map is not required. As still another example, the processing circuitry 51 displays a screen on which the order of the MR imaging in the imaging protocol is specified.

Examples of the memory 53 include a Hard Disk Drive (HDD), a Solid-State Drive (SDD), and a storage device, such as an integrated circuitry storage device, for storing various types of information. Examples of the memory 53 also include a compact disc read only memory (CD-ROM) drive, a digital versatile disc (DVD) drive, and a driving apparatus for reading and writing information from/to a portable storage medium, such as a flash memory.

The display 55 displays various types of information via the display control function 516. Examples of the display 55 suitably used include a Cathode Ray Tube (CRT) display, a Liquid Crystal Display (LCD), an organic electroluminescence (EL) display, a Light Emitting Diode (LED) display, a plasma display, and other optional displays known in this technical field.

The input interface 57 includes input devices for accepting various commands from the user. Examples of usable input devices include a keyboard, a mouse, various switches, a touch screen, and a touch pad. Input devices are not limited to devices having physical operating components, such as a mouse and a keyboard. Other examples of the input interface 57 include electrical signal processing circuitry for receiving an electrical signal corresponding to an input operation from an external input device separately provided from the magnetic resonance imaging apparatus 1 and outputting the received electrical signal to various types of circuitry. The input interface 57 may also be a sound recognition apparatus for converting an audio signal acquired by a microphone into an instruction signal.

The communication interface 59 is an interface for connecting the magnetic resonance imaging apparatus 1 with a workstation, a Picture Archiving and Communication System (PACS), a Hospital Information System (HIS), a Radiology Information System (RIS), and the like via a Local Area Network (LAN) and the like. The network interface (IF) transmits and receives variety of information to/from the connected workstation, PACS, HIS, and RIS.

Processing for generating the second magnetic field distribution map via the generation function 513 will be described below.

The processing circuitry 51 applies a trained model to the first magnetic field distribution map, the first anatomical image, and/or a processed image to generate the second magnetic field distribution map via the generation function 513. As described above, the first magnetic field distribution map acquired by the shimming imaging has the first spatial resolution lower than the second spatial resolution of the first anatomical image acquired by the first MR imaging. Hereinafter the first magnetic field distribution map is referred to as a low-resolution shimming map. The second magnetic field distribution map has the third spatial resolution higher than the spatial resolution of a first shimming map. Hereinafter the second magnetic field distribution map is referred to as a high-resolution shimming map. The first anatomical image and/or the processed image having the second spatial resolution higher than the spatial resolution of the low-resolution shimming map is referred to as a high-resolution anatomical image and/or the processed image, respectively. The magnitude relation between the second and the third spatial resolutions is not particularly limited. The second and the third spatial resolutions may be the same, or the second spatial resolution may be higher or lower than the third spatial resolution.

The trained model is a machine learning model trained based on training samples including input data, which is the low-resolution shimming map, the high-resolution anatomical image, and/or the processed image, and output data, which is the high-resolution shimming map. The trained model is generated, for example, by the generation function 513. As an input to the trained model, the user can optionally select whether to use the anatomical image, the processed image, or both the anatomical image and the processed image. Unless otherwise noted, an anatomical image is used as an input to the trained model.

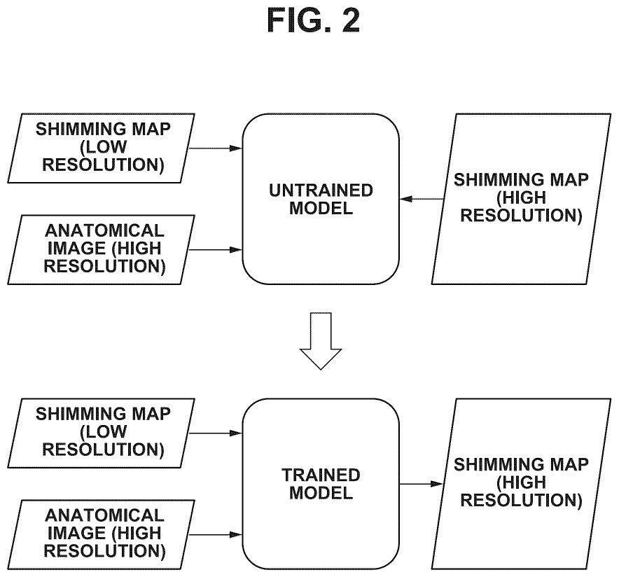

FIG. 2 is a diagram illustrating an example of generation processing of the trained model according to the present embodiment. As illustrated in FIG. 2, the processing circuitry 51 trains an untrained model based on a plurality of training samples including input data, which is the low-resolution shimming map and the high-resolution anatomical image, and output data, which is the high-resolution shimming map. The high-resolution shimming map is used as ground truth data. Hereinafter the high-resolution shimming map included in the training samples is referred to as a ground truth shimming map. The low-resolution shimming map, the high-resolution anatomical image, and the high-resolution shimming map are data related to the same subject, and may be acquired in the same single inspection or in different inspections.

The high-resolution shimming map may be a shimming map reconstructed based on the k-space data acquired by the shimming imaging with a high spatial resolution, or the shimming map generated by applying super-resolution processing to the shimming map reconstructed based on the k-space data acquired by the shimming imaging with a low spatial resolution. The same subject or different subjects may be used for acquiring a plurality of training samples. The low-resolution shimming map, the high-resolution anatomical image, and the high-resolution shimming map may be artificially generated data instead of data acquired by the MR imaging.

An untrained model indicates a machine learning model before optimization of weight parameters and network parameters, such as biases. More specifically, a neural network is used as a machine learning model. The machine learning model has a combination of an input layer, an output layer, a fully binding layer, a convolutional layer, a pooling layer, a normalization layer, an attention mechanism, and other optional network layers. The network configuration of the machine learning model is not particularly limited. Any network configuration is applicable as long as image data can be input and output. Examples of applicable network configurations include a Convolutional Neural Network (CNN) mainly composed of a convolutional layer, and a Vision Transformer (ViT) which applies a transformer to image processing. The transformer is a network block mainly composed of a multi-head attention mechanism as a development form of the attention mechanism. The transformer has a network configuration including a serial connection of a residual block between the multi-head attention mechanism and the normalization layer having a residual connection with the multi-head attention mechanism, and a residual block between a fully binding layer and the normalization layer having a residual connection with the fully binding layer.

A shimming map is an image expressing shapes of anatomical regions and having a similar outer appearance to an anatomical image. However, a shimming map has a different feature from an anatomical image, i.e., the phase fluctuates significantly at anatomical regions but fluctuates smoothly in anatomical regions. Therefore, the anatomical image, together with the shimming map, is input to a trained model. This enables the machine learning model to learn the correlation between the low-resolution and the high-resolution shimming maps while factoring in high-resolution anatomical regions represented by the anatomical image, thus improving the accuracy of the high-resolution shimming map.

As an example, the processing circuitry 51 updates the network parameters of the untrained model through the supervised training based on a plurality of training samples, by using an optional optimization algorithm. The probabilistic gradient descent, Adam, and other algorithms are applicable as optimization algorithms. For example, the processing circuitry 51 applies forward propagation processing corresponding to the network configuration of the untrained model to a combination of the low-resolution shimming map and the high-resolution anatomical image to generate a predictive shimming map. Then, the processing circuitry 51 calculates a loss value as the error between the predictive shimming map and the ground truth shimming map, based on a loss function. The processing circuitry 51 updates the parameters of the untrained model in such a manner that the loss value is decreased.

The processing circuitry 51 repeats the generation of the predictive shimming map, the calculation of the loss value, and the updating of parameters until the end condition is satisfied. Examples of the end condition include the number of repetitions reaching a predetermined number of times, the loss value converging to a value less than a predetermined value, and the accuracy of the predictive shimming map reaching a predetermined value. A set of parameters when the end condition is satisfied is stored in the memory 53 as optimal parameters. A machine learning model assigned the optimal parameters is used as a trained model.

The training algorithm of an untrained model is not limited to the supervised learning. A suitable algorithm needs to be selected from among the supervised training, the self-supervised training, and the unsupervised training, in accordance with the network configuration of the untrained model.

In the operation phase, the processing circuitry 51 applies the combination of the low-resolution shimming map and the high-resolution anatomical image related to a subject to a trained model to generate the high-resolution shimming map related to the subject. Using the trained model enables generating the high-resolution shimming map without performing the high-resolution shimming imaging. More specifically, the trained model applies super-resolution processing to the low-resolution shimming map to generate the high-resolution shimming map.

An example of an MR examination operation by the magnetic resonance imaging apparatus 1 will be described below.

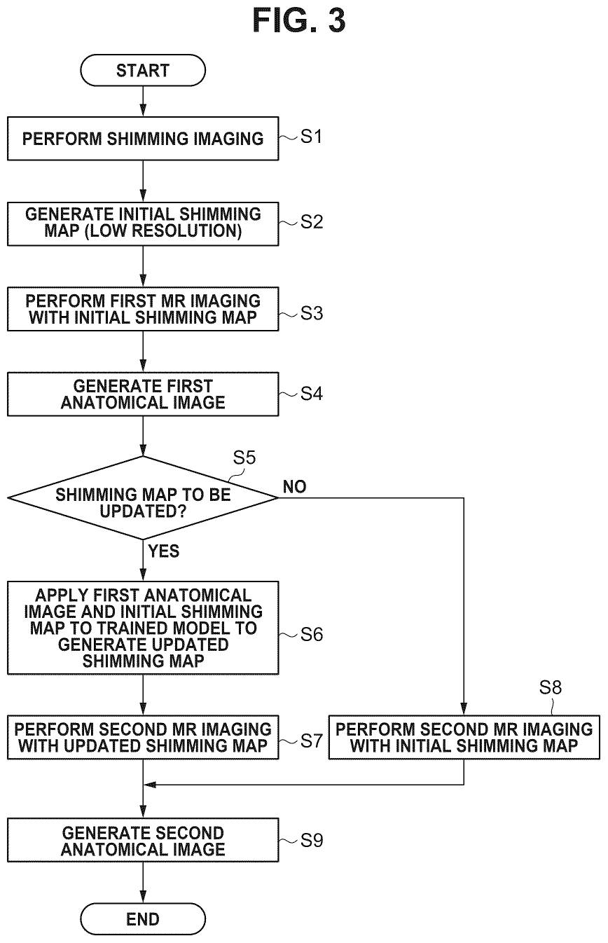

FIG. 3 is a diagram illustrating a typical processing procedure of the MR inspection by the magnetic resonance imaging apparatus 1 according to the present embodiment. A trained model has already been generated before starting the MR inspection and stored in the memory 53 or the like. In the present embodiment, the second MR imaging is anatomical image capturing.

Referring to FIG. 3, in step S1, the processing circuitry 51 controls the imaging mechanism 10 via the first imaging control function 517 to perform the shimming imaging on the subject P. In the shimming imaging, k-space data is acquired by the receiver circuitry 25. The acquired k-space data is acquired by the processing circuitry 51 via the acquisition function 512. In the shimming imaging, either a pulse sequence of two-dimensional imaging or a pulse sequence of three-dimensional imaging may be performed.

After completion of step S1, in step S2, the processing circuitry 51 generates a low-resolution initial shimming map via the reconstruction function 514 based on the k-space data acquired in step S1. As an example, in step S1, the sequence control circuitry 29 performs a pulse sequence of a low-resolution gradient echo twice, and the receiver circuitry 25 acquires two sets of the k-space data. In step S2, the processing circuitry 51 generates the low-resolution initial shimming map that is the spatial distribution of the deviation of the static magnetic field, based on the two sets of the k-space data. The initial shimming map is stored in the memory 53. The processing circuitry 51 calculates the correction magnetic field coefficient based on the initial shimming map. The correction magnetic field coefficient is stored in the memory 53 in association with the initial shimming map.

After completion of step S2, in step S3, the processing circuitry 51 controls the imaging mechanism 10 via the second imaging control function 518 to perform the first MR imaging on the subject P according to the correction magnetic field coefficient. More specifically, the sequence control circuitry 29 controls the shim coil power source 26 based on the correction magnetic field coefficient based on the low-resolution initial shimming map to supply a current to the shim coil 49 according to the correction magnetic field coefficient, and superimposes the correction magnetic field on the static magnetic field applied to the imaging region. Then, the sequence control circuitry 29 controls the gradient magnetic field power source 21, the transmitter circuitry 23, and the receiver circuitry 25 according to the imaging condition for the first MR imaging to perform the first MR imaging. Thus, the first MR imaging is performed under the static magnetic field with the deviation acquired based on the initial shimming map. The k-space data acquired by the receiver circuitry 25 is acquired by the processing circuitry 51 via the acquisition function 512. In the first MR imaging, either a pulse sequence of two-dimensional imaging or a pulse sequence of three-dimensional imaging may be performed.

After completion of step S3, in step S4, the processing circuitry 51 generates, via the reconstruction function 514, an anatomical image based on the k-space data acquired in step S3. The anatomical image is an MR image in which morphology of the imaging target region within the subject P is visualized. Examples of anatomical images that is to be generated include a T1 weighted image, a T2 weighted image, and a Fluid Attenuated Inversion Recovery (FLAIR) image. The anatomical image is stored in the memory 53 in association with the shimming map and the correction magnetic field coefficient.

After completion of step S4, in step S5, the processing circuitry 51 determines whether the shimming map is to be updated. In a case where the instruction function 515 issues an instruction to update the shimming map (YES in step S5), the processing circuitry 51 determines to update the shimming map. Ina case where the instruction function 515 does not issue an instruction to update the shimming map (NO in step S5), the processing circuitry 51 determines not to update the shimming map. For example, in a case where the second MR imaging requires a high resolution, it is desirable to update the shimming map because the high-resolution shimming map is required. With the smaller the Field Of View (FOV), the second MR imaging is desirably to be performed with a higher resolution.

There are various methods for issuing an instruction to update the shimming map. For example, a first method issues an instruction to update the shimming map by using a Graphical User Interface (GUI) button, and a second method issues an instruction to update the shimming map in an imaging protocol editing screen.

With the first method, the processing circuitry 51 displays, via the display control function 516, a first button indicating that the update of the first magnetic field distribution map (shimming map) is required, and a second button indicating that the update of the relevant map is not required. When the first button is pressed, the processing circuitry 51 issues an instruction to generate the second magnetic field distribution map via the instruction function 515.

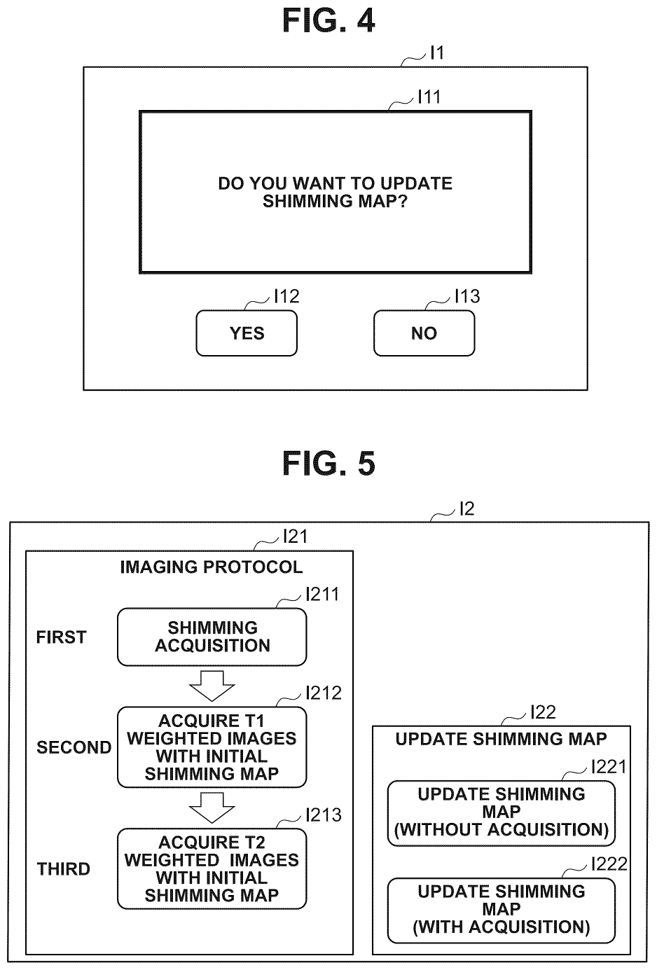

FIG. 4 is a diagram illustrating an example of a display screen I1 of GUI buttons for issuing an instruction to update the shimming map. The display screen I1 is displayed on the display 55. The display screen I1 includes a display field I11, a YES button I12, and a NO button I13. The display field I11 displays a message for making an inquiry about whether to update the first shimming map, such as “Do You Want to Update Shimming Map?”. The YES button I12 is a GUI button for receiving the instruction to update the first shimming map. In a case where the YES button I12 is pressed, the processing circuitry 51 determines to update the first shimming map. The NO button I13 is a GUI button for receiving the instruction not to update the first shimming map. In a case where the NO button I13 is pressed, the processing circuitry 51 determines not to update the first shimming map.

With the second method, the processing circuitry 51 displays, via the display control function 516, a display screen (hereinafter referred to as an editing screen) on which the order of different types of MR imaging in the imaging protocol is specified. In a case where an operation for adding generation of the second magnetic field distribution map (shimming map) to the imaging protocol is performed, the processing circuitry 51 issues an instruction to generate the second magnetic field distribution map (shimming map) via the instruction function 515.

FIG. 5 is a diagram illustrating an example of an editing screen I2 of the imaging protocol in an initial state. The editing screen I2 in an initial state means an editing screen that is displayed before an operation for adding shimming map generation is performed. As illustrated in FIG. 5, the editing screen I2 includes a display field I21 for displaying the imaging protocol, and a display field I22 in which GUI parts for updating the shimming map are arranged. In the display field I21, GUI parts indicating different types of MR imaging registered in the imaging protocol are arranged in the order of imaging. Referring to FIG. 5, for example, GUI parts I211, I212, and I213 are arranged in this order from the top downward. The GUI part I211 labeled “SHIMMING ACQUISITION” relates to the shimming imaging as first imaging. The GUI part I212 labeled “ACQUIRE T1 WEIGHTED IMAGES WITH INITIAL SHIMMING MAP” relates to the first MR imaging as second imaging. The GUI part I213 labeled “ACQUIRE T2 WEIGHTED IMAGES WITH INITIAL SHIMMING MAP” relates to the second MR imaging as third imaging. The GUI parts I211, I212, and I213 can be operated with the mouse or the like serving as the input interface 57. For example, the GUI parts can be changed in order, deleted, and/or added. The display field I22 displays GUI parts I221 and I222. The GUI part I221 labeled “UPDATE SHIMMING MAP (WITHOUT ACQUISITION)” indicates processing of updating the shimming map without additional shimming imaging. The GUI part I222 labeled “UPDATE SHIMMING MAP (WITH ACQUISITION)” indicates processing of updating the shimming map with additional shimming imaging. The GUI parts I221 and I222 can be operated with the mouse or the like. For example, the GUI parts I221 and I222 can be add to any desired position between the GUI parts I211, I212, and I213 arranged in the display field I21.

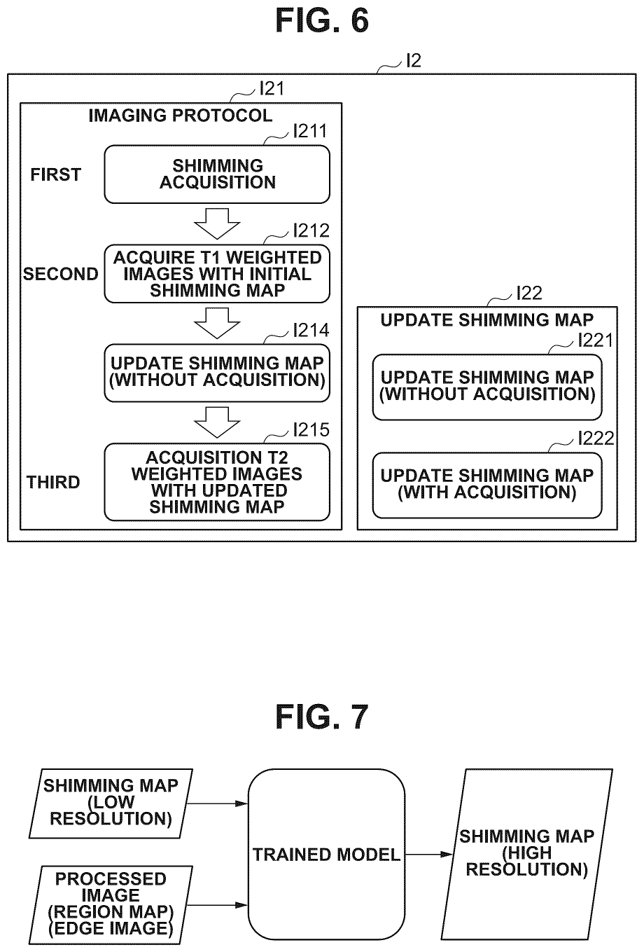

FIG. 6 is a diagram illustrating an example of the editing screen I2 after the imaging protocol has been edited. FIG. 6 illustrates an example case where a label “UPDATE SHIMMING MAP (WITHOUT ACQUISITION)” is added between the second and the third MR imaging. For example, a user operation with the mouse or the like inserts the GUI part I221 between the GUI part I212 for the first MR imaging and the GUI part I213 for the second MR imaging in the display field I21 in FIG. 5. With this operation, the processing circuitry 51 will issue an instruction to generate a second shimming map. In this case, as illustrated in the display field I21 in FIG. 6, a GUI part I214 labeled “UPDATE SHIMMING MAP (WITHOUT ACQUISITION)” is arranged between the GUI part I212 for the first MR imaging and a GUI part I215 for the second MR imaging. Due to the insertion of the GUI part I214, imaging is performed by using the second shimming map in the second MR imaging, and thus the label of the GUI part I215 may be corrected to, for example, “ACQUIRE T2 WEIGHTED IMAGES WITH UPDATED SHIMMING MAP”.

In a case where the processing circuitry 51 determines to update the shimming map (YES in step S5), the processing proceeds to step S6. In step S6, the processing circuitry 51 reads the first anatomical image generated by the generation function 513 in step S4 and the low-resolution initial shimming map (first shimming map) generated in step S2 from the memory 53, and applies the read first anatomical image and the read low-resolution initial shimming map to the trained model to generate a high-resolution updated shimming map (second shimming map). The high-resolution updated shimming map is stored in the memory 53. The high-resolution updated shimming map can be generated by using the trained model without performing additional high-resolution shimming imaging. This enables reducing the load on the magnetic resonance imaging apparatus 1 accompanied by the additional shimming imaging, reducing the labor on radiological technicians, doctors, and other health workers, and reducing the burden on the subject P.

In step S6, the processing circuitry 51 further calculates the correction magnetic field coefficient based on the high-resolution updated shimming map. Since the correction magnetic field coefficient has been calculated based on the high-resolution updated shimming map, the accuracy is expected to be higher than accuracy of the correction magnetic field coefficient based on the low-resolution initial shimming map. The correction magnetic field coefficient is stored in the memory 53 in association with the updated shimming map. In a case where the high-resolution updated shimming map and/or the correction magnetic field coefficient are stored in the memory 53, the processing circuitry 51 may delete the low-resolution shimming map and/or the correction magnetic field coefficient from the memory 53. This can prevent an occurrence of an event using the low-resolution shimming map and/or the correction magnetic field coefficient in the second MR imaging.

After completion of step S6, in step S7, the processing circuitry 51 performs, via the third imaging control function 519, the second MR imaging with the updated shimming map generated in step S6. More specifically, the sequence control circuitry 29 controls the shim coil power source 26 based on the correction magnetic field coefficient based on the high-resolution updated shimming map to supply a current to the shim coil 49 according to the correction magnetic field coefficient, and superimposes the correction magnetic field on the static magnetic field being applied to the imaging region. Then, the sequence control circuitry 29 controls the gradient magnetic field power source 21, the transmitter circuitry 23, and the receiver circuitry 25 according to the imaging condition for the second MR imaging to perform the second MR imaging. Thus, the second MR imaging is performed under the static magnetic field with the deviation corrected based on the updated shimming map. This enables the second MR imaging to be performed with a high spatial resolution. The k-space data acquired by the receiver circuitry 25 is acquired by the processing circuitry 51 via the acquisition function 512. In the second MR imaging, either a pulse sequence of two-dimensional imaging or a pulse sequence of three-dimensional imaging may be performed.

In step S9, the processing circuitry 51 generates, via the reconstruction function 514, the second anatomical image based on the k-space data acquired in step S7. Examples of images to be generated as the second anatomical images include a T1 weighted image, T2 weighted image, and a FLAIR image. As described above, the second anatomical image is acquired by the second MR imaging under the static magnetic field with the deviation corrected based on the updated shimming map. Thus, the second anatomical image is expected to be a high-quality image having a smaller amount of distortion caused by the deviation of the static magnetic field in comparison with the first anatomical image based on the initial shimming map. The second anatomical image is displayed, for example, on the display 55 and provided for image diagnoses or other uses by the user.

In a case where the processing circuitry 51 determines not to update the shimming map (NO in step S5), the processing proceeds to step S8. In step S8, the processing circuitry 51 performs, via the third imaging control function 519, the second MR imaging with the shimming map generated in step S2. In this case, the sequence control circuitry 29 controls the shim coil power source 26 based on the correction magnetic field coefficient based on the initial shimming map to supply a current to the shim coil 49 according to the correction magnetic field coefficient, and superimposes the correction magnetic field on the static magnetic field being applied to the imaging region. Then, the sequence control circuitry 29 controls the gradient magnetic field power source 21, the transmitter circuitry 23, and the receiver circuitry 25 according to the imaging condition for the second MR imaging to perform the second MR imaging. The k-space data acquired by the receiver circuitry 25 is acquired by the processing circuitry 51 via the acquisition function 512. In step S9, the processing circuitry 51 generates, via the reconstruction function 514, a second anatomical image based on the k-space data acquired in step S7. The generated anatomical image is displayed, for example, on the display 55 and provided for image diagnoses or other uses by the user.

After completion of step S9, the MR inspection according to the present embodiment is completed.

The MR inspection according to the present application is not limited to the flowchart in FIG. 3. Optional processing can be added, deleted, and/or modified without departing from the spirit and scope of this application.

### First Modification

While anatomical image capturing has been described above as an example of the second MR imaging, MR spectrum imaging, such as Magnetic Resonance Spectroscopy (MRS) imaging and Chemical Exchange Saturation Transfer (CEST) imaging, may also be applicable. An MRS spectrum can be generated by the MRS imaging, and a Z spectrum can be generated by the CEST imaging.

### Second Modification

The processing circuitry 51 according to a second modification may generate a high-resolution shimming map based on a low-resolution shimming map by using the processed image. More specifically, the processing circuitry 51 applies a low-resolution shimming map and a processed image to a trained model to generate a high-resolution shimming map. The trained model according to the second modification will be described below.

FIG. 7 is a diagram illustrating an example of inputs and an output of the trained model according to the second modification. As illustrated in FIG. 7, the trained model according to the second modification inputs a low-resolution shimming map and a processed image and outputs a high-resolution shimming map. The processed image has enhanced boundaries of anatomical regions included in the first anatomical image. The processed image is generated by the processing circuitry 51.

As an example, the processing circuitry 51 applies segmentation processing to a first anatomical image to divide each anatomical region included in the first anatomical image, and assigns a specific pixel value to each anatomical region to generate a region map as a processed image. The region map includes pixel value differences at a boundary of each anatomical region, and thus the boundaries are enhanced. As another example, the processing circuitry 51 applies edge enhancement processing to the first anatomical image to generate an edge image as a processed image having enhanced boundaries of anatomical regions included in the first anatomical image. The processing circuitry 51 may apply edge enhancement processing to the region map to generate an edge image. These processed images are based on the first anatomical image and thus can be considered as high-resolution images.

By replacing the anatomical image in FIG. 2 with a processed image, the trained model according to the second modification can be generated with a method similar to the method for the trained model illustrated in FIG. 2. More specifically, the processing circuitry 51 can train an untrained model based on a plurality of training samples including input data, which is the low-resolution shimming map and the high-resolution processed image, and output data, which is the high-resolution shimming map. Thus, the untrained model learns a correlation between the combination of the low-resolution shimming map with the high-resolution processed image and the high-resolution shimming map. Static magnetic field deviations exhibit a characteristic behavior in which the deviations fluctuate smoothly within the same anatomical region but fluctuate significantly at the boundaries between anatomical regions. Therefore, the untrained model can accurately learn the feature of the shimming map through learning factoring in processed images having enhanced boundaries.

### Third Modification

A function that is employed to extract sparsity in Compressed Sensing (CS) may be incorporated in the trained model. Incorporating the function means introducing a sparsification layer, which is a network layer designed to sparsify spatial differences, into the model to be trained.

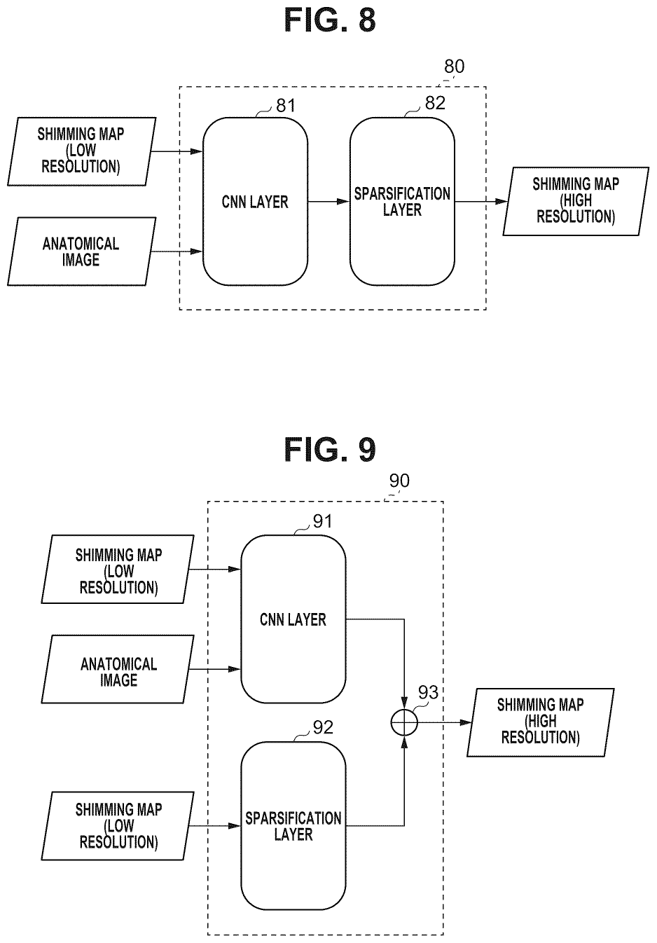

FIG. 8 is a diagram illustrating an example of a network configuration of a trained model 80 according to a third modification. As illustrated in FIG. 8, the trained model 80 includes a CNN layer 81 and a sparsification layer 82 connected in series. The CNN layer 81 is a neural network mainly composed of a convolutional layer, more specifically, a network layer that applies forward propagation processing including convolutional processing to a low-resolution shimming map and a high-resolution anatomical image, and outputs a shimming map subjected to the forward propagation processing. The sparsification layer 82 is a network layer that applies compressed sensing to the shimming map output from the CNN layer 81 and outputs a high-resolution shimming map.

As an example, the sparsification layer 82 sparsifies the shimming map output from the CNN layer 81 to generate a sparse image, and calculates a spatial difference of the sparse image. Then, while ensuring consistency between the shimming map reconstructed based on the calculated spatial difference and the low-resolution shimming map, the sparsification layer 82 updates the shimming map so that the spatial difference is minimized. The shimming map with the minimized spatial difference is output as the high-resolution shimming map. Total variation or L1 norm may be used as spatial differences. Wavelet transform and inverse transform may be used for sparsification and reconstruction.

The trained model 80 illustrated in FIG. 8 includes a single block including the CNN layer 81 and the sparsification layer 82 connected in series. However, an unrolled network in which any desired number of (at least two) the blocks are connected in series is also applicable. In this case, learnable parameters of each CNN layer 81 may be handled as different parameters or shared parameters. The trained model 80 can be trained based on a plurality of training samples including input data, which is the low-resolution shimming map and the high-resolution anatomical image, and output data, which is the high-resolution shimming map, on an end-to-end basis.

An input to the trained model 80 is not limited to an anatomical image. Instead of an anatomical image, a processed image may be input or both an anatomical image and a processed image may be input. Instead of the CNN layer 81, other networks, such as a vision transformer layer, may be provided or a combination of the CNN layer 81 and the vision transformer layer may be used.

### Fourth Modification

FIG. 9 is a diagram illustrating an example of a network configuration of a trained model 90 according to a fourth modification. As illustrated in FIG. 9, the trained model 90 includes a CNN layer 91, a sparsification layer 92, and an addition layer 93. The output sides of the CNN layer 91 and the sparsification layer 92 are connected in parallel to the addition layer 93. Similar to the CNN layer 81 illustrated in FIG. 8, the CNN layer 91 is a network layer that applies forward propagation processing including convolutional processing to a low-resolution shimming map and a high-resolution anatomical image, and outputs a shimming map subjected to the forward propagation processing. The sparsification layer 92 is a network layer that applies compressed sensing to the low-resolution shimming map and outputs an estimated shimming map. The addition layer 93 is a network layer that adds the shimming map from the CNN layer 91 and the initial shimming map from the sparsification layer 92 and outputs a high-resolution shimming map.

The trained model 90 illustrated in FIG. 9 includes a single block including the CNN layer 91, the sparsification layer 92, and the addition layer 93. However, an unrolled network in which any desired number of (at least two) the blocks are connected in series is also applicable. The trained model 90 can be trained based on a plurality of training samples including input data, which is the low-resolution shimming map and the high-resolution anatomical image, and output data, which is the high-resolution shimming map, on an end-to-end basis. Instead of the anatomical image, a processed image may be input to the trained model 90.

An input to the trained model 90 is not limited to an anatomical image. Instead of an anatomical image, a processed image may be input or both an anatomical image and a processed image may be input. Instead of the CNN layer 91, other networks, such as a vision transformer layer, may be provided or a combination of the CNN layer 91 and the vision transformer layer may be used.

### Fifth Modification

In the MR inspection procedure illustrated in FIG. 3, in a case where the processing circuitry 51 determines to update the shimming map (YES in step S5), then in step S6, the processing circuitry 51 generates the second shimming map. However, the present embodiment is not limited thereto. Even in a case where an instruction to generate the second shimming map is not issued, the processing circuitry 51 may automatically generate the second shimming map after generating the first anatomical image in step S4.

### Sixth Modification

In the MR inspection procedure illustrated in FIG. 3, the processing circuitry 51 performs the shimming imaging for the low-resolution shimming map once. However, the present embodiment is not limited thereto. For example, the processing circuitry 51 may perform the shimming imaging several times when the subject P moves between the shimming imaging (step S1) and the first MR imaging (step S3) and when the low-resolution shimming map is to be simply acquired again. In this case, the processing circuitry 51 may generate the second magnetic field distribution map by using the first anatomical image and/or the processed image acquired after the last shimming imaging, without using the first anatomical image and/or the processed image acquired before the last shimming imaging. This can reduce an anatomical difference between the shimming map and the first anatomical image and/or the processed image input to the trained model. The processing circuitry 51 may delete the first anatomical image and/or the processed image acquired before the last shimming imaging from the memory 53.

The magnetic resonance imaging apparatus according to some of the above-described embodiments includes the imaging mechanism 10 and the processing circuitry 51. The imaging mechanism 10 is a mechanism for performing the MR imaging. The processing circuitry 51 controls the imaging mechanism 10 to perform the shimming imaging to acquire the first magnetic field distribution map having the first spatial resolution. The processing circuitry 51 controls the imaging mechanism 10 to perform the first MR imaging to acquire the first anatomical image having the second spatial resolution higher than the first spatial resolution. The processing circuitry 51 generates the second magnetic field distribution map having the third spatial resolution higher than the first spatial resolution by using the first magnetic field distribution map, the first anatomical image, and/or a processed image having enhanced boundaries of anatomical regions included in the first anatomical image.

With the above-described configuration, a magnetic field distribution map having a high spatial resolution can be generated, without performing shimming imaging with a high spatial resolution, by using the first magnetic field distribution map acquired in the shimming imaging with a low spatial resolution. Shimming imaging with a low spatial resolution can be performed in a shorter imaging time in comparison with high-resolution shimming imaging. Thus, according to the present embodiment, a magnetic field distribution map having a high spatial resolution can be generated in a short imaging time. Using the second magnetic field distribution map having a high spatial resolution enables the second MR imaging to be performed with a high spatial resolution following the first MR imaging. Therefore, an improvement in the throughput of MR inspections can be expected.

According to at least one of the above-described embodiments, a magnetic field distribution map having a high spatial resolution can be acquired in a short imaging time.

The term “processor” used in the description of the foregoing embodiments refers to a circuit such as a central processing unit (CPU), a graphics processing unit (GPU), an application specific integrated circuit (ASIC), and a programmable logic device (e.g., a simple programmable logic device [SPLD], a complex programmable logic device [CPLD], or a field programmable gate array [FPGA]). The processor implements functions by reading and executing a program stored in a memory circuit. Instead of storing the programs in the storage circuit, the programs may be directly built in the processor circuit. In such a case, the processor implements the functions by reading the built-in programs in its own circuit and executing the programs. Alternatively, in a case where the processor is, for example, an ASIC (Application-Specific Integrated Circuit), the function is implemented as a logic circuit directly embedded within the processor's circuitry, rather than by executing a program stored in a memory circuit. The processors according to the exemplary embodiments are not limited to a single-circuit configuration. A plurality of independent circuits may be combined into a processor that implements the functions. The functions of a plurality of components illustrated in FIG. 1 may alternatively be implemented by integrating them into a single processor.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
an imaging mechanism configured to perform MR imaging; and
processing circuitry configured to:
control the imaging mechanism to perform shimming imaging to acquire a first magnetic field distribution map having a first spatial resolution;
control the imaging mechanism to perform first MR imaging to acquire a first anatomical image having a second spatial resolution higher than the first spatial resolution; and
generate a second magnetic field distribution map having a third spatial resolution higher than the first spatial resolution by using the first magnetic field distribution map, the first anatomical image, and/or a processed image having enhanced boundaries of anatomical regions included in the first anatomical image.

2. The magnetic resonance imaging apparatus according to claim 1,
wherein a trained model is applied to the first magnetic field distribution map, the first anatomical image, and/or the processed image to generate the second magnetic field distribution map, and
wherein the trained model receives the first magnetic field distribution map, the first anatomical image, and/or the processed image, as inputs and outputs the second magnetic field distribution map.

3. The magnetic resonance imaging apparatus according to claim 2, wherein the trained model includes
a first network layer configured to apply forward propagation processing to the first magnetic field distribution map, the first anatomical image, and/or the processed image, and output a third magnetic field distribution map; and
a second network layer configured to apply compressed sensing to the third magnetic field distribution map, and output the second magnetic field distribution map.

4. The magnetic resonance imaging apparatus according to claim 2, wherein the trained model includes
a first network layer configured to apply forward propagation processing to the first magnetic field distribution map, the first anatomical image, and/or the processed image, and output a third magnetic field distribution map;
a second network layer configured to apply compressed sensing to the first magnetic field distribution map, and output a fourth magnetic field distribution map; and
a third network layer configured to add the third magnetic field distribution map and the fourth magnetic field distribution map, and output the second magnetic field distribution map.

5. The magnetic resonance imaging apparatus according to claim 1,
wherein the processing circuitry further configured to issue, after the first anatomical image is acquired, an instruction to generate the second magnetic field distribution map, and
wherein, upon issuance of an instruction to generate the second magnetic field distribution map, the second magnetic field distribution map is generated.

6. The magnetic resonance imaging apparatus according to claim 5,
wherein the processing circuitry further configured to display a first button indicating that an update of the first magnetic field distribution map is to be instructed and a second button indicating that an update of the first magnetic field distribution map is not to be instructed, and
wherein, in a case where the first button is pressed, an instruction to generate the second magnetic field distribution map is issued.

7. The magnetic resonance imaging apparatus according to claim 5,
wherein the processing circuitry further configured to display a display screen on which an order of MR imaging in imaging protocol is specified, and
wherein, in a case where an operation to add generation of the second magnetic field distribution map to the imaging protocol is performed, an instruction to generate the second magnetic field distribution map is issued.

8. The magnetic resonance imaging apparatus according to claim 1, wherein, in a case where shimming imaging for the first magnetic field distribution map is performed several times, the second magnetic field distribution map is generated by using the first anatomical image and/or the processed image acquired after last shimming imaging, without using the first anatomical image and/or the processed image acquired before the last shimming imaging.

9. The magnetic resonance imaging apparatus according to claim 1, wherein the processed image is an image generated by applying segmentation processing to the first anatomical image, or an image generated by applying edge enhancement processing to the first anatomical image.

10. The magnetic resonance imaging apparatus according to claim 1, wherein the processing circuitry further configured to control the imaging mechanism by using the second magnetic field distribution map to perform second MR imaging, to acquire a second anatomical image or an MR spectrum.

11. A magnetic resonance imaging method comprising:
controlling an imaging mechanism to perform shimming imaging to acquire a first magnetic field distribution map having a first spatial resolution;
controlling the imaging mechanism to perform first MR imaging to acquire a first anatomical image having a second spatial resolution higher than the first spatial resolution;
generating a second magnetic field distribution map having a third spatial resolution higher than the first spatial resolution by using the first magnetic field distribution map, the first anatomical image, and/or a processed image having enhanced boundaries of anatomical regions included in the first anatomical image; and
controlling the imaging mechanism by using the second magnetic field distribution map to perform second MR imaging, to acquire a second anatomical image or an MR spectrum.
